(19) United States
(12) Patent Application Publication
(10) Pub. No.: US 2025/0370330 A1
(43) Pub. Date: Dec. 4, 2025

(54) IMPRINT APPARATUS, IMPRINT METHOD AND ARTICLE MANUFACTURING METHOD

(71) Applicant: CANON KABUSHIKI KAISHA, Tokyo (JP)

(72) Inventors: TAKAHIRO TOYOSHIMA, Tochigi (JP); MASAHIRO TAMURA, Tochigi (JP)

(21) Appl. No.: 19/210,026

(22) Filed: May 16, 2025

(30) Foreign Application Priority Data
May 30, 2024 (JP) 2024-088273

(51) Int. Cl. G03F 7/00; G03F 9/00

(52) U.S. Cl. CPC G03F 7/0002; G03F 9/7042

(57) ABSTRACT

An imprint apparatus including a driving unit configured to relatively drive a mold and a substrate, a measuring unit configured to measure, for each of a plurality of substrates loaded into the imprint apparatus, a distance between the mold and the substrate, and a controller configured to, in a state in which a predetermined gas is being supplied to a space under the mold, control the driving unit based on the distance measured by the measuring unit such that the distance is an equal distance between the plurality of substrates until the substrate is driven from a first position for arranging an imprint material on the substrate to a second position where the imprint material on the substrate faces the mold.

### BACKGROUND

### Field of the Technology

The present disclosure relates to an imprint apparatus, an imprint method and an article manufacturing method.

### Description of the Related Art

As a lithography technique for manufacturing a device such as a semiconductor element, there is known an imprint technique of transferring the pattern of a mold to an imprint material on a substrate, thereby forming a pattern on a nanometer order. An imprint apparatus to which the imprint technique is applied cures an imprint material arranged (supplied) on a substrate while molding it using a mold, thereby forming a pattern of the imprint material on the substrate.

As one of imprint material curing methods in the imprint apparatus, there is a photo-curing method. The photo-curing method is a method of curing the imprint material by irradiating it with light in a state in which the imprint material arranged on the substrate is in contact with the mold, and separating the mold from the cured imprint material, thereby forming a pattern of the imprint material on the substrate.

In the imprint apparatus, when molding the imprint material on the substrate using the mold, air (atmosphere) may stay as a residual gas in a process space between the mold and the substrate, and bubbles may mix into the imprint material. In this case, a portion of the mold where the imprint material is not filled is a defect, and the pattern of the mold is not correctly transferred.

A technique of supplying a predetermined gas (process gas) to the process space between the mold and the substrate is proposed in Japanese Patent Laid-Open No. 2007-509769. Japanese Patent Laid-Open No. 2007-509769 discloses a technique of filling the process space with a permeable gas and dissolving or diffusing the permeable gas remaining in the imprint material or the mold, thereby quickly decreasing the residual gas. There is also a technique of pressing the mold against the imprint material in a state in which the process space is filled with a condensable gas, thereby decreasing the condensable gas to a few hundredth and suppressing the influence of the residual gas.

To the process space between the mold and the substrate, a predetermined gas is supplied from a gas supply unit arranged on the periphery of a mold holder that holds the mold. Also, an arranging unit (for example, a dispenser) configured to arrange the imprint material on the substrate is generally provided at a position farther than the gas supply unit when viewed from the mold. Hence, the predetermined gas can be drawn into the process space by driving the substrate such that the imprint material arranged from the arranging unit onto the substrate passes under the gas supply unit that supplies the predetermined gas and is located under the mold. However, the concentration of the predetermined gas in the process space may lower due to the influence of drawing of air around the process space together with the predetermined gas or the influence of air remaining the process space.

A technique of suppressing in lowering of the concentration of the predetermined gas in the process space is proposed in Japanese Patent No. 6018405. Japanese Patent No. 6018405 discloses a technique of reducing the distance between the mold and the substrate during the period from the start of supply of the predetermined gas until the imprint material on the substrate is located under the mold, thereby suppressing lowering of the concentration of the predetermined gas in the process space.

However, the concentration of the predetermined gas in the process space between the mold and the substrate contributes to curing of the imprint material on the substrate. Hence, if the concentration of the predetermined gas in the process space is too high, curing of the imprint material progresses before alignment between the mold and the substrate is completed, and the overlay accuracy (alignment accuracy) between the mold and the substrate lowers. Also, if the concentration of the predetermined gas in the process space is too low, curing of the imprint material on the substrate takes time, or bubbles are mixed into the imprint material, resulting in a defect in the pattern formed on the substrate.

As described above, in the process space between the mold and the substrate, the important thing is not to lower the concentration of the predetermined gas but to maintain the concentration set as an imprint condition, that is, not to cause a fault due to a change of the imprint environment. On the other hand, if the mold or the substrate is changed (exchanged), the distance between the mold and the substrate changes because of the thickness difference between individuals and, therefore, the concentration of the predetermined gas in the process space is affected.

### SUMMARY

The present disclosure provides a technique advantageous in terms of reproducibility of the concentration of a predetermined gas in a space between a mold and a substrate.

According to one aspect of the present disclosure, there is provided an imprint apparatus for forming a pattern of an imprint material on a substrate using a mold, including a driving unit configured to relatively drive the mold held by a mold holder and the substrate held by a substrate holder, a measuring unit configured to measure, for each of a plurality of substrates loaded into the imprint apparatus, a distance between the mold held by the mold holder and the substrate held by the substrate holder, and a controller configured to, in a state in which a predetermined gas is being supplied to a space under the mold held by the mold holder, control the driving unit based on the distance measured by the measuring unit such that the distance is an equal distance between the plurality of substrates until the substrate is driven from a first position for arranging the imprint material on the substrate to a second position where the imprint material on the substrate faces the mold.

Features of the present disclosure will become apparent from the following description of embodiments with reference to the attached drawings. The following description of embodiments are described by way of example.

### BRIEF DESCRIPTION OF THE DRAWINGS

FIG. 1 is a schematic view illustrating configurations of an imprint apparatus according to an aspect of the present disclosure.

FIGS. 2A and 2B are views for describing imprint processing of a conventional technique.

FIGS. 3A and 3B show views for describing imprint processing according to the embodiment.

FIGS. 4A and 4B show views for describing imprint processing according to the embodiment.

FIGS. 5A and 5B are views for describing measurement necessary for obtaining the distance between a mold and a substrate.

FIGS. 6A to 6F are views for describing an article manufacturing method.

### DESCRIPTION OF THE EMBODIMENTS

Hereinafter, embodiments will be described in detail with reference to the attached drawings. Note, the following embodiments are not intended to limit the scope of the claims. Multiple features are described in the embodiments, but it is not the case that all such features are required, and multiple such features may be combined as appropriate. Furthermore, in the attached drawings, the same reference numerals are given to the same or similar configurations, and redundant description thereof is omitted.

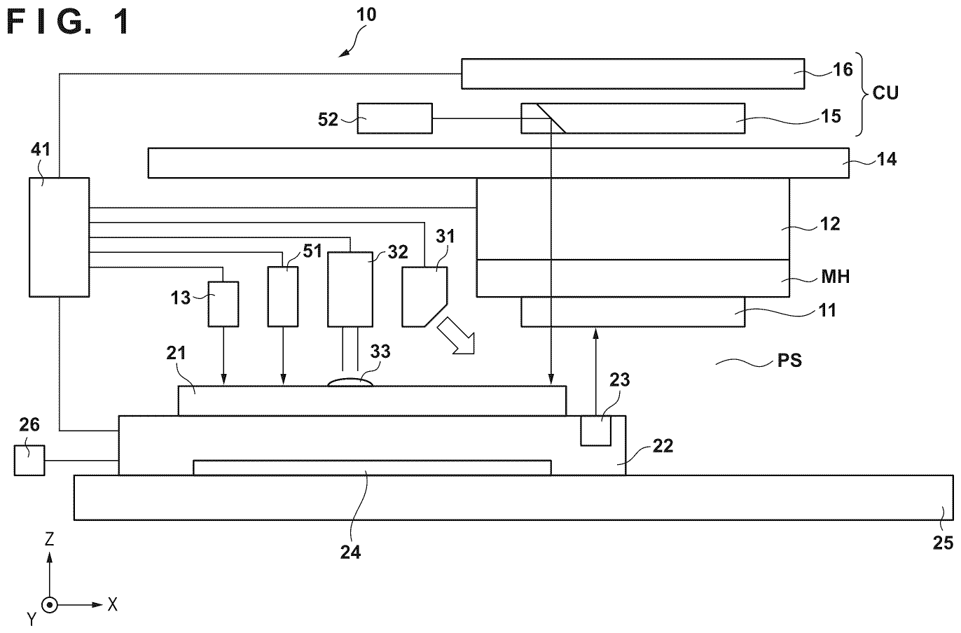

FIG. 1 is a schematic view illustrating configurations of an imprint apparatus 10 according to an aspect of the present disclosure. The imprint apparatus 10 is a lithography apparatus employed in a lithography step that is a manufacturing step for a device such as a semiconductor element, a liquid crystal display element, or magnetic storage medium as an article to form a pattern on a substrate. The imprint apparatus 10 brings an imprint material arranged (supplied) on the substrate into contact with the mold, and applies curing energy to the imprint material, thereby forming a pattern of a cured product to which the pattern of the mold is transferred.

As the imprint material, a material (curable composition) to be cured by receiving curing energy is used. An example of the curing energy that is used is electromagnetic waves, heat, or the like. As the electromagnetic waves, for example, infrared light, visible light, ultraviolet light, and the like selected from the wavelength range of 10 nm (inclusive) to 1 mm (inclusive) is used.

The curable composition is a composition cured by light irradiation or heating. The photo-curable composition cured by light irradiation contains at least a polymerizable compound and a photopolymerization initiator, and may contain a nonpolymerizable compound or a solvent, as needed. The nonpolymerizable compound is at least one type of material selected from a group comprising of a sensitizer, a hydrogen donor, an internal mold release agent, a surfactant, an antioxidant, a polymer component, and the like.

The imprint material may be applied in a film shape onto the substrate by a spin coater or a slit coater. The imprint material may be applied, onto the substrate, in a droplet shape or in an island or film shape formed by connecting a plurality of droplets using a liquid injection head. The viscosity (the viscosity at 25° C.) of the imprint material is, for example, 1 mPa's (inclusive) to 100 mPa·s (inclusive).

As the substrate, glass, ceramic, a metal, a semiconductor, a resin, or the like is used, and a member made of a material different from that of the substrate may be formed on the surface of the substrate, as needed. More specifically, examples of the substrate include a silicon wafer, a semiconductor compound wafer, silica glass, and the like.

In the specification and the accompanying drawings, directions will be indicated on an XYZ coordinate system in which directions parallel to a plane on which the substrate is placed are defined as the X-Y plane. Directions parallel to the X-axis, the Y-axis, and the Z-axis of the XYZ coordinate system are the X direction, the Y direction, and the Z direction, respectively. A rotation about the X-axis, a rotation about the Y-axis, and a rotation about the Z-axis are OX, OY, and OZ, respectively.)

The imprint apparatus 10 molds an imprint material 33 on a substrate using a mold 11 and forms a pattern of the imprint material 33. As shown in FIG. 1, the imprint apparatus 10 includes a mold holder MH, a mold driving unit 12, a substrate stage 22, a substrate driving unit 24, and a measuring unit 26. Furthermore, the imprint apparatus 10 includes a gas supply unit 31, an arranging unit 32, a curing unit CU, a substrate measuring unit 13, a mold measuring unit 23, a coarse alignment measuring unit 51, a precise alignment measuring unit 52, and a controller 41.

The mold holder MH has a function of holding the mold 11. The mold holder MH, for example, attracts the outer peripheral region of the mold 11 by a vacuum attraction force or an electrostatic force, thereby holding the mold 11.

The mold driving unit 12 is supported by a structure 14. The mold driving unit 12 drives (the mold 11 held by) the mold holder MH. The mold driving unit 12 is configured to drive the mold holder MH at least in a direction (Z direction) of moving the mold 11 close to or apart from a substrate 21. Hence, the mold driving unit 12 has a function of performing a pressing operation of bringing (pressing) the mold 11 into contact with the imprint material 33 on the substrate and a mold release operation of separating the mold 11 from the cured imprint material 33 on the substrate. However, the mold driving unit 12 is preferably configured to drive the mold holder MH concerning a plurality of directions (for example, three directions including the Z direction, the OX direction, the OY direction, preferably six directions including the X direction, the Y direction, the Z direction, the OX direction, the OY direction, and the OZ direction).

The substrate stage 22 functions as a substrate holder that holds the substrate 21 via a substrate chuck. The substrate stage 22 attracts the substrate 21 by a vacuum attraction force or an electrostatic force, thereby holding it.

On a stage base 25, the substrate driving unit 24 drives the substrate 21 held by the substrate stage 22. The substrate driving unit 24 is configured to drive the substrate stage 22 at least in directions (the X direction and the Y direction) along (the upper surface of) the stage base 25. Hence, the substrate driving unit 24 has a function of conveying the substrate 21 along a conveyance path between an arranging position (first position) to arrange the imprint material 33 on the substrate and a pressing position (second position) to press the mold 11 to the imprint material 33 on the substrate. The pressing position is a position where the imprint material 33 on the substrate faces the mold 11 held by the mold holder MH. However, the substrate driving unit 24 is preferably configured to drive the substrate stage 22 concerning a plurality of directions (for example, three directions including the Z direction, the OX direction, the OY direction, preferably six directions including the X direction, the Y direction, the Z direction, the OX direction, the OY direction, and the OZ direction).

In this embodiment, the mold driving unit 12 and the substrate driving unit 24 function as driving units that relatively drive the mold 11 held by the mold holder MH and the substrate 21 held by the substrate stage 22 such that the relative position between the mold 11 and the substrate 21 is adjusted.

The measuring unit 26 includes, for example, a laser interferometer or an encoder and obtains stage position information by measuring the position of the substrate stage 22. The stage position information obtained by the measuring unit 26 is used for alignment of the substrate stage 22.

The gas supply unit 31 is arranged on the outer side (periphery) of the mold holder MH and the mold driving unit 12, more specifically, between the arranging position and the pressing position. The gas supply unit 31 supplies a predetermined gas (process gas) to a process space PS under the mold 11 held by the mold holder MH. The process space PS is a space defined between the mold 11 and the substrate 21 in a state in which the mold 11 held by the mold holder MH faces the substrate 21 held by the substrate stage 22. The process gas includes, for example, a permeable gas and a condensable gas.

When pressing the mold 11 to the imprint material 33 on the substrate, if air (atmosphere) stays in the process space PS, it may be a residual gas, and bubbles may mix into the imprint material 33. In this case, a portion of the mold 11 where the imprint material 33 is not filled is a defect, and the pattern of the mold 11 is not correctly transferred. However, when a permeable gas is supplied as a predetermined gas from the gas supply unit 31 to the process space PS, the process space is filled with the permeable gas, and dissolving or diffusing the permeable gas remaining in the imprint material 33 or the mold 11, thereby quickly decreasing the residual gas.

The arranging unit 32 is arranged at the arranging position that is a position farther than the gas supply unit 31 (a position on the outer side of the gas supply unit 31) when viewed from the mold 11 held by the mold holder MH. The arranging unit 32 includes a dispenser that discharges the imprint material 33, and supplies the imprint material 33 onto the substrate 21 via the dispenser, thereby arranging the imprint material 33 on the substrate. The imprint material 33 is appropriately selected in accordance with various kinds of conditions such as the manufacturing steps of an article such as a semiconductor element, and in this embodiment, the imprint material 33 is a photo-curable composition that has a property of curing upon irradiation of ultraviolet rays (light).

The curing unit CU has a function of curing the imprint material 33 on the substrate. The curing unit CU includes a light source 16 that generates ultraviolet rays as light used to cure the imprint material 33, and an irradiation optical system 15 that irradiates the imprint material 33 on the substrate with the ultraviolet rays from the light source 16 via the mold 11. The irradiation optical system 15 may include an optical element that adjusts the ultraviolet rays from the light source 16 to a state appropriate for imprint processing.

The substrate measuring unit 13 is arranged on the periphery of the mold 11 held by the mold holder MH, for example, at a position farther than the arranging unit 32 (a position on the outer side of the arranging unit 32) when viewed from the mold 11, and has a function of measuring the substrate 21. The substrate measuring unit 13 includes a measuring device (distance sensor) that measures the distance from the substrate measuring unit 13 to the surface of the substrate 21 held by the substrate stage 22 in, for example, the Z direction, and a spectral interference system capable of measuring the displacement of the substrate 21 without contact. In this embodiment, the substrate measuring unit 13 obtains height position information concerning the height (the position in the Z direction) of the surface of the substrate 21 held by the substrate stage 22 with respect to the device reference of the imprint apparatus 10.

The mold measuring unit 23 is arranged on the lower side of the mold 11, for example, on the substrate stage 22, and has a function of measuring the mold 11. The mold measuring unit 23 includes a measuring device (distance sensor) that measures the distance from the mold measuring unit 23 to the surface of the mold 11 held by the mold holder MH in, for example, the Z direction, and a spectral interference system capable of measuring the displacement of the mold without contact. In this embodiment, the mold measuring unit 23 obtains height position information concerning the height (the position in the Z direction) of the surface of the mold 11 held by the mold holder MH with respect to the device reference of the imprint apparatus 10.

The coarse alignment measuring unit 51 is arranged on the periphery of the mold 11 held by the mold holder MH, for example, between the substrate measuring unit 13 and the arranging unit 32. The coarse alignment measuring unit 51 includes an off-axis scope that detects a coarse alignment mark provided on the substrate 21 at a low magnification, and measures the position of the coarse alignment mark (the position deviation of the substrate 21). The coarse alignment measuring unit 51 is used for prealignment for driving the substrate stage 22 to a position where, for example, the precise alignment measuring unit 52 can detect a precise alignment mark provided on the substrate 21.

The precise alignment measuring unit 52 is arranged, for example, on the upper side of the mold 11 held by the mold holder MH. The precise alignment measuring unit 52 includes an on-axis scope that detects, via the mold 11, a precise alignment mark provided on the substrate 21 at a high magnification, and measures the position of the precise alignment mark (the position deviation of the substrate 21). The precise alignment measuring unit 52 is used for fine alignment for obtaining, for example, the precise positions (shot array) of the shot regions of the substrate 21.

The controller 41 is formed by an information processing apparatus (computer) including a CPU and a memory. The controller 41 generally controls the units of the imprint apparatus 10 in accordance with a program stored in a storage unit and thus operates the imprint apparatus 10. The controller 41 controls imprint processing of transferring the pattern of the mold 11 to the imprint material 33 on the substrate and forming the pattern of the imprint material 33 on the substrate.

Imprint processing that is the operation of the imprint apparatus 10 will be described here in detail. First, the substrate stage 22 is driven such that the substrate 21 is located at the arranging position under the arranging unit 32, and the imprint material 33 is arranged from the arranging unit 32 to the target shot region on the substrate. Next, the substrate stage 22 is driven such that the target shot region on the substrate with the imprint material 33 arranged thereof is located at the pressing position under the mold 11. Then, the mold holder MH is driven by the mold driving unit 12, thereby bringing the mold 11 into contact with the imprint material 33 on the substrate and pressing, and thus molding the imprint material 33 by the mold 11. When driving (the substrate 21 held by) the substrate stage 22 from the arranging position to the pressing position, a predetermined gas is supplied from the gas supply unit 31 to the process space PS. Note that the gas supply unit 31 starts supplying the predetermined gas at least until the substrate 21 moves to the pressing position, and preferably starts supplying the predetermined gas until the substrate 21 passes under the gas supply unit 31 arranged between the arranging position and the pressing position. Next, in a state in which the imprint material 33 on the substrate is in contact with the mold, ultraviolet rays from the light source 16 are guided by the irradiation optical system 15 to irradiate the imprint material 33 on the substrate via the mold 11, thereby curing the imprint material 33. Next, the mold holder MH is driven by the mold driving unit 12, thereby separating the mold 11 from the cured imprint material 33 on the substrate. With the series of steps, the pattern of the mold 11 is transferred to the imprint material 33 arranged in the target shot region on the substrate, and the pattern of the imprint material 33 is formed on the target shot region.

In the imprint processing, as described above, while supplying the predetermined gas from the gas supply unit 31 to the process space PS, the substrate stage 22 is driven to move the substrate 21 from the arranging position to the pressing position, thereby drawing the predetermined gas into the process space PS. To the process space PS, however, air (atmosphere) around the process space PS is also drawn together with the predetermined gas. The concentration of the predetermined gas in the process space PS is affected by the ratio of the air and the predetermined gas drawn in to the process space PS or (the difference of) the amount of air remaining in the process space PS. Hence, if the mold 11 or the substrate 21 is changed (exchanged), the distance between the mold 11 and the substrate 21 changes because of the thickness difference between individuals and, therefore, the concentration of the predetermined gas in the process space PS is affected.

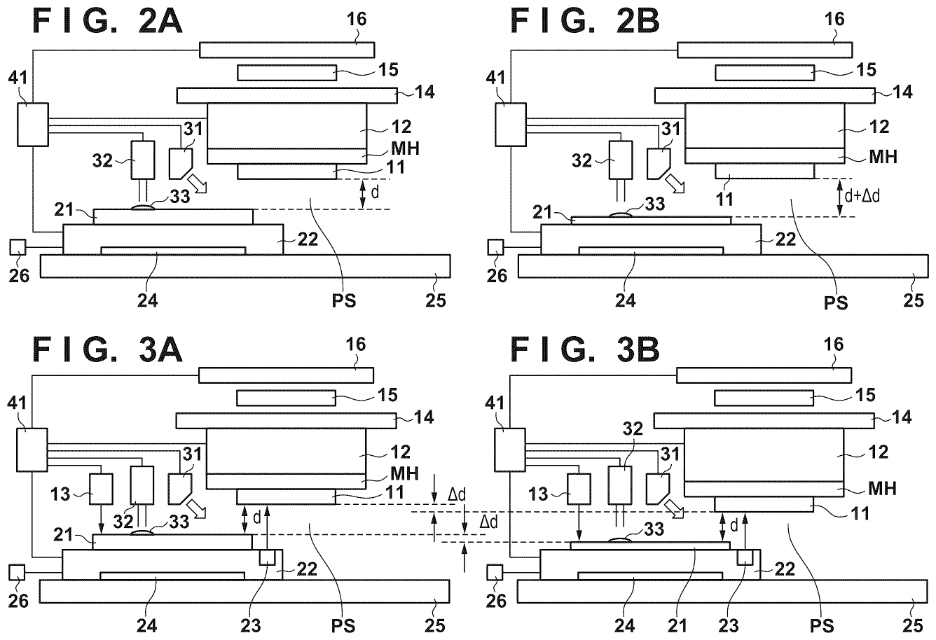

Imprint processing in the conventional technique will be described with reference to FIGS. 2A and 2B particularly focusing on processing concerning supply of the predetermined gas to the process space PS. FIG. 2A conceptually shows the imprint apparatus 10 at the time of setting of an imprint condition concerning imprint processing. FIG. 2B conceptually shows the imprint apparatus 10 when at least one of the mold 11 and the substrate 21 is changed (exchanged) from the time of setting of the imprint condition.

FIG. 2A shows that at the time of setting of the imprint condition, the distance between the mold 11 held by the mold holder MH and the substrate 21 held by the substrate stage 22 is a set distance d that is preset as the imprint condition. FIG. 2B shows that at least one of the mold 11 and the substrate 21 is changed, and the distance between the mold 11 and the substrate 21 changes to distance d+Δd due to the thickness difference Δd between individuals. If the difference Δd is positive, the process space PS under the mold 11 becomes wide as compared to the time of setting of the imprint condition, and the concentration of the predetermined gas in the process space PS is affected in a direction to be lower. On the other hand, if the difference Δd is negative, the process space PS under the mold 11 becomes narrow as compared to the time of setting of the imprint condition, and the concentration of the predetermined gas in the process space PS is affected in a direction to be higher.

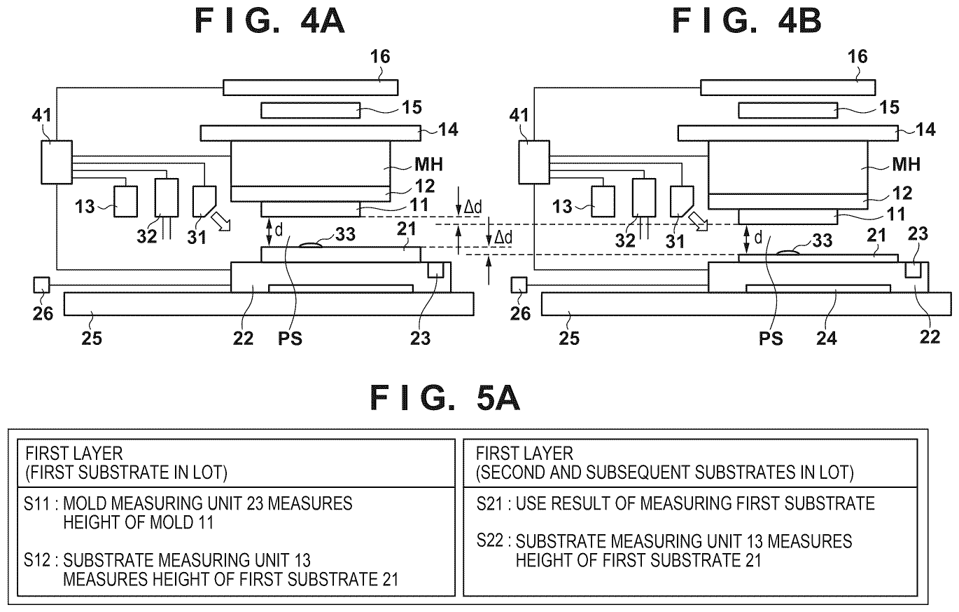

Imprint processing according to this embodiment will be described with reference to FIGS. 3A, 3B, 4A and 4B particularly focusing on processing concerning supply of the predetermined gas to the process space PS. FIG. 3A conceptually shows the imprint apparatus 10 at the time of setting of an imprint condition concerning imprint processing. FIG. 3B conceptually shows the imprint apparatus 10 when at least one of the mold 11 and the substrate 21 is changed (exchanged) from the time of setting of the imprint condition.

FIG. 3A shows that at the time of setting of the imprint condition, the distance between the mold 11 held by the mold holder MH and the substrate 21 held by the substrate stage 22 is the set distance d that is preset a the imprint condition, as in the conventional technique. FIG. 3B shows a state in which at least one of the mold 11 and the substrate 21 is changed, and the mold driving unit 12 drives the mold 11 held by the mold holder MH to cancel the thickness difference Δd of the individual. In this embodiment, when at least one of the mold 11 and the substrate 21 is changed, the distance between the mold 11 held by the mold holder MH and the substrate 21 held by the substrate stage 22 is adjusted to the set distance d that is preset as the imprint condition. Since this prevents the process space PS under the mold 11 from becoming wide or narrow, the concentration of the predetermined gas in the process space PS is not affected, and the concentration at the time of setting of the imprint condition can be reproduced.

The substrate 21 has a tendency that the thickness difference between individuals is large, as compared to the mold 11. For example, the substrate 21 is processed basically on a lot basis, but the variation of thickness is large even between a plurality of substrates included in a lot. Hence, it is particularly useful that for each of a plurality of substrates 21 (between the plurality of substrates) loaded into the imprint apparatus 10, the distance between the mold 11 held by the mold holder MH and the substrate 21 held by the substrate stage 22 becomes an equal distance.

In this embodiment, first, for each of the plurality of substrates 21 loaded into the imprint apparatus 10, the substrate measuring unit 13 measures the height of the substrate 21 held by the substrate stage 22 and obtains height position information (first height information). Also, the mold measuring unit 23 measures the height of the mold 11 held by the mold holder MH and obtains height position information (second height information). The controller 41 obtains the distance between the mold 11 held by the mold holder MH and the substrate 21 held by the substrate stage 22 based on the height position information obtained by the substrate measuring unit 13 and the height position information obtained by the mold measuring unit 23. Thus, in this embodiment, the substrate measuring unit 13, the mold measuring unit 23, and the controller 41 function as a measuring unit that measures the distance between the mold 11 held by the mold holder MH and the substrate 21 held by the substrate stage 22. In a state in which the predetermined gas is supplied to the process space PS under the mold 11, the controller 41 controls the mold driving unit 12 or the substrate driving unit 24 based on the distance obtained by the measuring unit such that the distance between the mold 11 and the substrate 21 is an equal distance (set distance d) between the plurality of substrates. Note that in this embodiment, since the distance between the mold 11 and the substrate 21 can correctly be measured, the distance between the mold 11 and the substrate 21 can be adjusted correctly and arbitrarily.

FIGS. 4A and 4B conceptually show the imprint apparatus 10 when the substrate 21 is driven from the arranging position (FIGS. 3A and 3B) to the pressing position. As shown in FIGS. 4A and 4B, in this embodiment, the mold driving unit 12 or the substrate driving unit 24 is controlled such that until the substrate 21 is driven from the arranging position to the pressing position, the distance between the mold 11 and the substrate 21 is an equal distance (set distance d) between the plurality of substrates. In addition, the mold driving unit 12 or the substrate driving unit 24 is preferably controlled such that until the substrate 21 passes under the gas supply unit 31, the distance between the mold 11 and the substrate 21 is an equal distance between the plurality of substrates. Furthermore, the mold driving unit 12 or the substrate driving unit 24 is preferably controlled such that until the substrate 21 passes under the gas supply unit 31 and is located at the arranging position, the distance between the mold 11 and the substrate 21 is kept equal between the plurality of substrates. Since this can make the ratio of air and the predetermined gas drawn into the process space PS under the mold 11 or the amount of air remaining in the process space PS equal between the plurality of substrates, it is advantageous in terms of reproducibility of the concentration of the predetermined gas in the process space PS. For example, while the substrate 21 is being moved from the arranging position to the pressing position, the distance between the mold 11 and the substrate 21 is maintained at the set distance d, thereby reproducing the concentration at the time of setting of the imprint condition as the concentration of the predetermined gas in the process space PS.

Also, when separating the mold 11 from the cured imprint material 33 on the substrate, the mold driving unit 12 is preferably controlled such that an acceleration concerning driving of raising the mold 11 is a set acceleration that is preset as the imprint condition. Furthermore, after the mold 11 is separated from the cured imprint material 33 on the substrate, the mold driving unit 12 or the substrate driving unit 24 is preferably controlled such that the distance between the mold 11 and the substrate 21 is an equal distance (set distance d) between the plurality of substrates. This is further advantageous in terms of reproducibility of the concentration of the predetermined gas in the process space PS. For example, this is advantageous in reproducing the concentration at the time of setting of the imprint condition as the concentration of the predetermined gas in the process space PS.

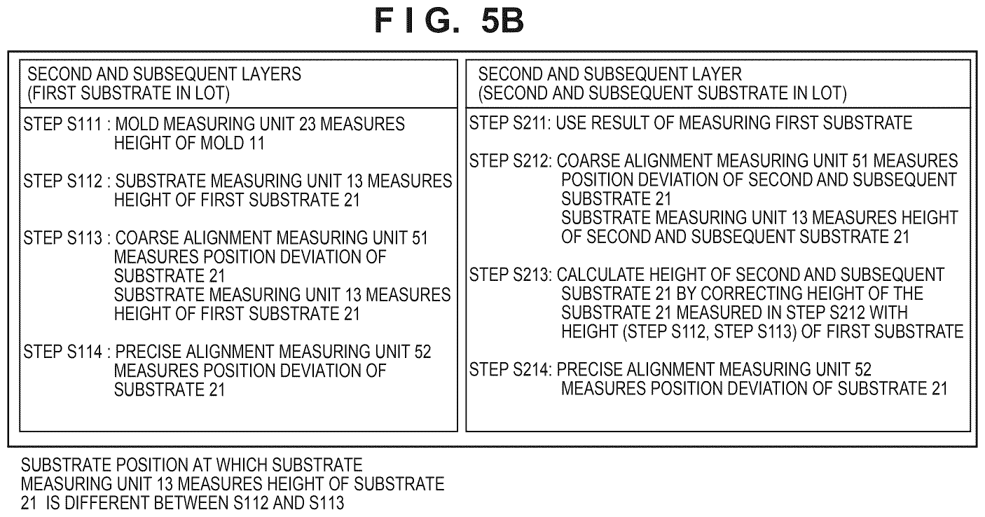

Additionally, as will be described below with reference to FIGS. 5A and 5B, as compared to the first substrate 21 (first substrate) in a lot, part of measurement necessary for obtaining the distance between the mold 11 and the substrate 21 can be omitted for the second substrate 21 (second substrate) in the lot.

FIG. 5A shows measurement processing necessary for obtaining the distance between the mold 11 and the substrate 21 for each of the first substrate 21 in the lot and the second or subsequent substrate 21 in the lot in imprint processing of a first layer.

Referring to FIG. 5A, for the first substrate 21, first, in S11, the mold measuring unit 23 measures the height of the mold 11 and obtains height position information (third height information). Next, in S12, the substrate measuring unit 13 measures the height of the first substrate 21 and obtains height position information (fourth height information). The controller 41 obtains the distance between the mold 11 held by the mold holder MH and the first substrate 21 held by the substrate stage 22 based on the height position information of the mold 11 obtained in S11 and the height position information of the first substrate 21 obtained in S12.

For the second or subsequent substrate 21, in S21, the height of the mold 11 is not measured by the mold measuring unit 23, and the height position information of the mold 11 obtained in S11 is used. Next, in S22, the substrate measuring unit 13 measures the height of the second or subsequent substrate 21 and obtains height position information (fifth height information). The controller 41 obtains the distance between the mold 11 held by the mold holder MH and the second or subsequent substrate 21 held by the substrate stage 22 based on the height position information of the mold 11 obtained in S11 and the height position information of the second or subsequent substrate 21 obtained in S22.

Thus, in the imprint processing of the first layer, measurement of the height of the mold 11 by the mold measuring unit 23 can be omitted for the second or subsequent substrate 21. It is therefore possible to suppress lowering of throughput derived from measurement for obtaining the distance between the mold 11 and the substrate 21.

FIG. 5B shows measurement processing necessary for obtaining the distance between the mold 11 and the substrate 21 for each of the first substrate 21 in the lot and the second or subsequent substrate 21 in the lot in imprint processing of a second or subsequent layer.

Referring to FIG. 5B, for the first substrate 21, first, in S111, the mold measuring unit 23 measures the height of the mold 11 and obtains height position information (sixth height information). Next, in S112, the substrate measuring unit 13 measures the height of the first substrate 21 and obtains height position information (seventh height information). Next, in S113, when the coarse alignment measuring unit 51 measures the position deviation (the position of the alignment mark) of the first substrate 21, the substrate measuring unit 13 measures the height of the first substrate 21 and obtains height position information (eighth height information). Here, the substrate position where the substrate measuring unit 13 measures the height of the first substrate 21 is different between S112 and S113. For example, in S112, the substrate measuring unit 13 measures the height of the substrate 21 in a state in which the substrate 21 is located at the first substrate position, and in S113, the substrate measuring unit 13 measures the height of the substrate 21 in a state in which the substrate is located at the second substrate position different from the first substrate position. The controller 41 obtains the distance between the mold 11 held by the mold holder MH and the first substrate 21 held by the substrate stage 22 based on the height position information of the mold 11 obtained in S111 and the height position information of the first substrate 21 obtained in S112. Next, in S114, the precise alignment measuring unit 52 measures the position deviation (the position of the alignment mark) of the first substrate 21.

For the second or subsequent substrate 21, in S211, the height of the mold 11 is not measured by the mold measuring unit 23, and the height position information of the mold 11 obtained in S111 is used. Next, in S212, when the coarse alignment measuring unit 51 measures the position deviation (the position of the alignment mark) of the second or subsequent substrate 21, the substrate measuring unit 13 measures the height of the second or subsequent substrate 21 and obtains height position information (ninth height information). Next, in S213, the controller 41 corrects the height position information obtained in S212 by the height position information obtained in S112 and the height position information obtained in S113, and calculates the height position information (height information) concerning the height of the second or subsequent substrate 21. More specifically, the difference between the height position information obtained in S112 and the height position information obtained in S113 is given to the height position information obtained in S212, thereby calculating the height position information concerning the height of the second or subsequent substrate 21. The height position information corresponds to height position information obtained by measuring the height of the second or subsequent substrate 21 by the substrate measuring unit 13 in a state in which the second or subsequent substrate 21 is located at the first substrate position. The controller 41 obtains the distance between the mold 11 and the second or subsequent substrate 21 based on the height position information of the mold 11 obtained in S111 and the height position information concerning the height of the second or subsequent substrate 21 calculated in S213. Next, in S214, the precise alignment measuring unit 52 measures the position deviation (the position of the alignment mark) of the second or subsequent substrate 21.

Thus, in the imprint processing of the second or subsequent layer, measurement of the height of the mold 11 by the mold measuring unit 23 and measurement of the height of the substrate 21 by the substrate measuring unit 13 at the first substrate position can be omitted for the second or subsequent substrate 21. It is therefore possible to suppress lowering of throughput derived from measurement for obtaining the distance between the mold 11 and the substrate 21.

The pattern of a cured product formed using the imprint apparatus 10 in the embodiment is used permanently for at least some of various kinds of articles or temporarily when manufacturing various kinds of articles. The articles are an electric circuit element, an optical element, a MEMS, a recording element, a sensor, a mold, and the like. Examples of the electric circuit element are volatile and nonvolatile semiconductor memories such as a DRAM, a SRAM, a flash memory, and a MRAM and semiconductor elements such as an LSI, a CCD, an image sensor, and an FPGA. Examples of the mold are molds for imprint.

The pattern of the cured product is directly used as the constituent member of at least some of the above-described articles or used temporarily as a resist mask. After etching or ion implantation is performed in the substrate processing step, the resist mask is removed.

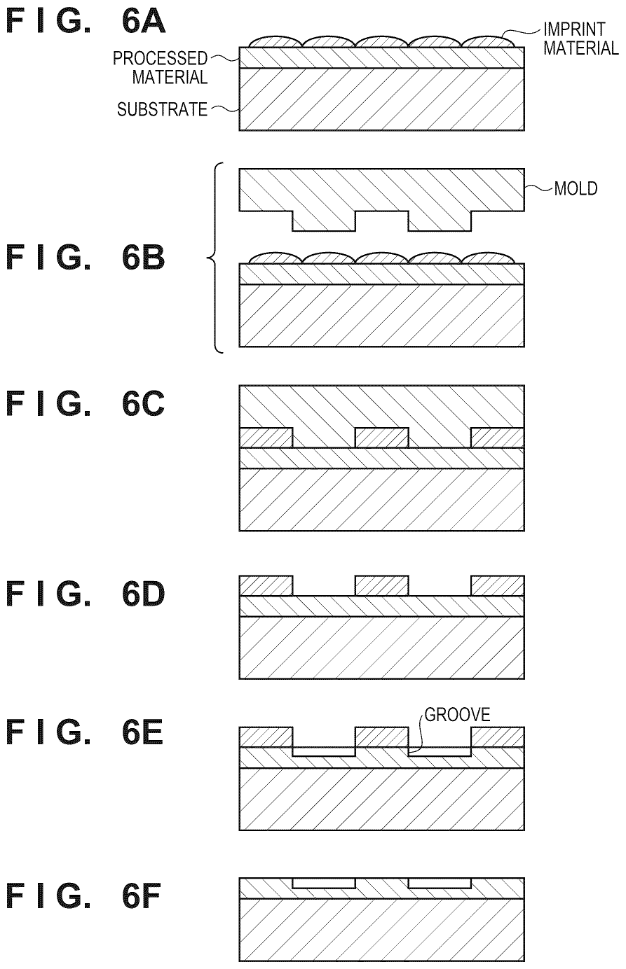

Next, description regarding a detailed method of manufacturing an article is given. As illustrated in FIG. 6A, the substrate such as a silicon wafer with a processed material such as an insulator formed on the surface is prepared. Next, an imprint material is applied to the surface of the processed material by an inkjet method or the like. A state in which the imprint material is applied as a plurality of droplets onto the substrate is shown here.

As shown in FIG. 6B, a side of the mold for imprint with a projection and groove pattern is formed on and caused to face the imprint material on the substrate. As illustrated in FIG. 6C, the substrate to which the imprint material is applied is brought into contact with the mold, and a pressure is applied. The gap between the mold and the processed material is filled with the imprint material. In this state, when the imprint material is irradiated with light serving as curing energy through the mold, the imprint material is cured.

As shown in FIG. 6D, after the imprint material is cured, the mold is released from the substrate. Thus, the pattern of the cured product of the imprint material is formed on the substrate. In the pattern of the cured product, the groove of the mold corresponds to the projection of the cured product, and the projection of the mold corresponds to the groove of the cured product. That is, the projection and groove pattern of the mold is transferred to the imprint material.

As shown in FIG. 6E, when etching is performed using the pattern of the cured product as an etching resistant mask, a portion of the surface of the processed material where the cured product does not exist or remains thin is removed to form a groove. As shown in FIG. 6F, when the pattern of the cured product is removed, an article with the grooves formed in the surface of the processed material can be obtained. The pattern of the cured material is removed here, but, for example, the pattern may be used as a film for insulation between layers included in a semiconductor element or the like without being removed after processing, in other words as a constituent member of the article.

While the present disclosure has been described with reference to exemplary embodiments, it is to be understood that the present disclosure is not limited to the disclosed exemplary embodiments. The scope of the following claims is to be accorded the broadest interpretation so as to encompass all such modifications and equivalent structures and functions.

This application claims the benefit of Japanese Patent application No. 2024-088273 filed on May 30, 2024, which is hereby incorporated by reference herein in its entirety.

What is claimed is:

1. An imprint apparatus for forming a pattern of an imprint material on a substrate using a mold, comprising:
a driving unit configured to relatively drive the mold held by a mold holder and the substrate held by a substrate holder;
a measuring unit configured to measure, for each of a plurality of substrates loaded into the imprint apparatus, a distance between the mold held by the mold holder and the substrate held by the substrate holder; and
a controller configured to, in a state in which a predetermined gas is being supplied to a space under the mold held by the mold holder, control the driving unit based on the distance measured by the measuring unit such that the distance is an equal distance between the plurality of substrates until the substrate is driven from a first position for arranging the imprint material on the substrate to a second position where the imprint material on the substrate faces the mold.

2. The apparatus according to claim 1, further comprising a supply unit provided between the first position and the second position and configured to supply the predetermined gas to the space,
wherein the controller controls the driving unit such that the distance is the equal distance between the plurality of substrates until the substrate passes under the supply unit.

3. The apparatus according to claim 2, wherein the controller controls the driving unit such that the distance is kept equal between the plurality of substrates until the substrate passes under the supply unit and is located at the second position.

4. The apparatus according to claim 1, wherein
the measuring unit includes:
a mold measuring unit configured to measure a height of the mold held by the mold holder and obtain first height information; and
a substrate measuring unit configured to measure a height of the substrate held by the substrate holder and obtain second height information, and
the distance is obtained based on the first height information and the second height information.

5. The apparatus according to claim 4, wherein
the plurality of substrates include a first substrate that is a first substrate in a lot, and a second substrate that is a second or subsequent substrate in the lot, and
in the measuring unit,
for the first substrate, the mold measuring unit measures the height of the mold and obtains third height information, the substrate measuring unit measures a height of the first substrate and obtains fourth height information, and the distance between the mold held by the mold holder and the first substrate held by the substrate holder is obtained based on the third height information and the fourth height information, and
for the second substrate, the mold measuring unit does not measure the height of the mold, the substrate measuring unit measures a height of the second substrate and obtains fifth height information, and the distance between the mold held by the mold holder and the second substrate held by the substrate holder is obtained based on the third height information and the fifth height information.

6. The apparatus according to claim 4, further comprising an alignment measuring unit configured to measure a position of an alignment mark provided on the substrate,
wherein the plurality of substrates include a first substrate that is a first substrate in a lot, and a second substrate that is a second or subsequent substrate in the lot,
for the first substrate, the mold measuring unit measures the height of the mold and obtains sixth height information, in a state in which the first substrate is located at a first substrate position, the substrate measuring unit measures a height of the first substrate and obtains seventh height information, when the alignment measuring unit measures the position of the alignment mark in a state in which the first substrate is located at a second substrate position different from the first substrate position, the substrate measuring unit measures the height of the first substrate and obtains eighth height information, and the distance between the mold held by the mold holder and the first substrate held by the substrate holder is obtained based on the sixth height information and the seventh height information, and
for the second substrate, the mold measuring unit does not measure the height of the mold, when the alignment measuring unit measures the position of the alignment mark in a state in which the second substrate is located at the second substrate position, the substrate measuring unit measures the height of the second substrate and obtains ninth height information, and the distance between the mold held by the mold holder and the second substrate held by the substrate holder is obtained based on height information obtained by correcting the sixth height information and ten ninth height information by the seventh height information and the eighth height information.

7. The apparatus according to claim 1, wherein the controller controls the driving unit such that the distance is set to the equal distance between the plurality of substrates by driving the mold held by the mold holder.

8. The apparatus according to claim 1, wherein the controller controls the driving unit such that the distance is a set distance that is preset as an imprint condition concerning imprint processing of forming a pattern of the imprint material on the substrate.

9. The apparatus according to claim 1, wherein the controller controls the driving unit such that the distance is the equal distance between the plurality of substrates after the mold is separated from cured imprint material on the substrate.

10. The apparatus according to claim 1, wherein the controller controls the driving unit such that an acceleration concerning driving of the mold is a set acceleration that is preset as an imprint condition concerning imprint processing of forming a pattern of the imprint material on the substrate in a case where the mold is released from cured imprint material on the substrate.

11. The apparatus according to claim 1, wherein the predetermined gas includes a permeable gas or a condensable gas.

12. An imprint method in an imprint apparatus for forming a pattern of an imprint material on a substrate using a mold, comprising:
measuring, for each of a plurality of substrates loaded into the imprint apparatus, a distance between the mold held by the mold holder and the substrate held by the substrate holder; and
in a state in which a predetermined gas is being supplied to a space under the mold held by the mold holder, controlling driving associated with one of the mold and the substrate based on the distance measured in the measuring such that the distance is an equal distance between the plurality of substrates until the substrate is driven from a first position for arranging the imprint material on the substrate to a second position where the imprint material on the substrate faces the mold.

13. An article manufacturing method comprising:
forming a pattern on a substrate using an imprint apparatus defined in claim 1;
processing the substrate on which the pattern is formed in the forming; and
manufacturing an article from the processed substrate.
